(19) United States
(12) Patent Application Publication
(10) Pub. No.: US 2026/0313926 A1
(43) Pub. Date: Oct. 8, 2026

(54) CRYSTALLINE DEFECT REDUCTION IN DOPED REGION

(71) Applicant: TEXAS INSTRUMENTS INCORPORATED, Dallas, TX (US)

(72) Inventors: Christopher Thompson, Salt Lake City, UT (US); Jonathan Lane, Sandy, UT (US); Robert Cassel, Lehi, UT (US)

(21) Appl. No.: 19/173,658

(22) Filed: Apr. 8, 2025

(51) Int. Cl. H10D 10/01; H01L 21/265; H01L 21/762; H10D 10/40

(52) U.S. Cl. CPC H10D 10/051; H10D 10/40; H10P 30/204; H10P 30/21; H10W 10/014; H10W 10/17

(57) ABSTRACT

The present disclosure generally relates to semiconductor processing for crystalline defect reduction in a doped region. In an example, a sub-collector region is formed in a semiconductor substrate. Forming the sub-collector region may include implanting a dopant into the semiconductor substrate and performing an anneal process after implanting the dopant. An isolation structure is formed in the semiconductor substrate after forming the sub-collector region. The isolation structure has a sidewall adjoining the sub-collector region. A collector layer is formed over the sub-collector region.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices.

### SUMMARY

An example described herein is a method. A sub-collector region is formed in a semiconductor substrate. An isolation structure is formed in the semiconductor substrate after forming the sub-collector region. The isolation structure has a sidewall adjoining the sub-collector region. A collector layer is formed over the sub-collector region.

Another example is a method. A dopant is implanted into a semiconductor substrate. An anneal process is performed after implanting the dopant. A sub-collector region including the dopant is formed in the semiconductor substrate as a result of performing the anneal process. A trench is etched in the semiconductor substrate after performing the anneal process. The trench has a sidewall adjoining the sub-collector region. The trench is filled with an isolation material to form an isolation structure. A collector layer is formed over the sub-collector region.

A further example is a semiconductor device. The semiconductor device includes a semiconductor substrate, an isolation structure, a sub-collector region of a bipolar junction transistor (BJT), a collector layer of the BJT, a base layer of the BJT, and an emitter layer of the BJT. The isolation structure is in the semiconductor substrate. The isolation structure includes a sidewall with a non-planar profile. The isolation structure laterally surrounds at least in part an area of the BJT in the semiconductor substrate. The sub-collector region is in the area. The sub-collector region laterally adjoins the sidewall of the isolation structure. The collector layer is on the area. The base layer is on the collector layer. The emitter layer is on the base layer.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 8 are respective cross-sectional views of a semiconductor device in intermediate stages of manufacturing according to some examples.

FIG. 9 is a cross-sectional view of a semiconductor device according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for reducing crystalline defects, such as stacking faults and/or twin defects, in a doped region. More particularly, examples described herein provide for crystalline defect reduction in a sub-collector region of a bipolar junction transistor (BJT). Some examples include forming a sub-collector region in a semiconductor substrate and, after forming the sub-collector region, forming an isolation structure in the semiconductor substrate. The isolation structure has a sidewall adjoining the sub-collector region. Forming the sub-collector region may include implanting a dopant of the sub-collector region into the semiconductor substrate and performing an anneal after implanting the dopant.

Generally, implanting a dopant into a semiconductor substrate can amorphize the portion of the semiconductor substrate into which the dopant is implanted. Subsequently, an anneal may be performed to activate the dopants and recrystallize the amorphized portion of the semiconductor substrate. If the amorphized portion adjoins another amorphous surface, such as a surface of an oxide, crystalline defects, such as stacking faults and/or twin defects, in the semiconductor substrate at the interface between the semiconductor substrate (e.g., the amorphized portion that is being recrystallized by the anneal) and the other amorphous surface (that is not capable of being crystallized) may be generated during the anneal. Stress between the amorphous surface and the semiconductor substrate may influence the generation of the crystalline defects at the interface. The crystalline defects may propagate through the portion of the semiconductor substrate that is recrystallized by the anneal. This may cause the crystalline defects to be at a surface of the semiconductor substrate where another layer is to be epitaxially grown. Epitaxial growth of a layer on a surface having crystalline defects can cause the crystalline defects to continue to propagate into and through the epitaxially grown layer. These crystalline defects in the semiconductor substrate and in any epitaxially grown layers can form a leakage path for electrons, which may have detrimental effects on the semiconductor device that is formed.

Examples described herein may reduce or avoid crystalline defect generation, such as generation of stacking faults and/or twin defects, by forming a doped region in a semiconductor substrate (e.g., a sub-collector region) before forming another structure in the semiconductor substrate with an amorphous surface interfacing with that doped region. For example, dopants are implanted into the semiconductor substrate and the semiconductor substrate is annealed before an isolation structure adjoining that doped region is formed in the semiconductor substrate. By performing such processing, the amorphous surface (e.g., of the isolation structure) is not present during the anneal, which may reduce or avoid generation of crystalline defects in the doped region. Rather, crystalline seeds from the semiconductor substrate are increased for the recrystallization. By reducing or avoiding such crystalline defects (e.g., stacking faults and/or twin defects), electrical operation of the semiconductor device may be improved, such as by reducing or avoiding leakage that may otherwise occur due to crystalline defects. Further, examples described herein may provide a robust solution that permits a wide range of implant species, implant energy, implant dose, implant angle, and thermally controlled diffusion as may be needed for a target application. Also, examples described herein may also be easily integrated into processing flows including other technologies, such as complementary metal-oxide-semiconductor (CMOS), static random access memory (SRAM), etc. Other benefits and advantages may be achieved.

Various examples are described subsequently. Although the specific examples may illustrate various aspects of the above generally described features, examples may incorporate any combination of the above generally described features (which are described in more detail in examples below).

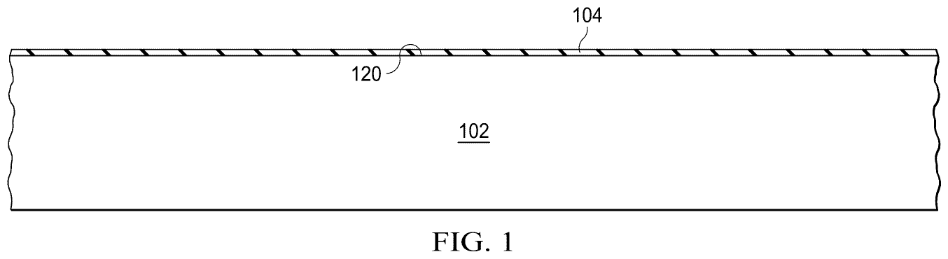

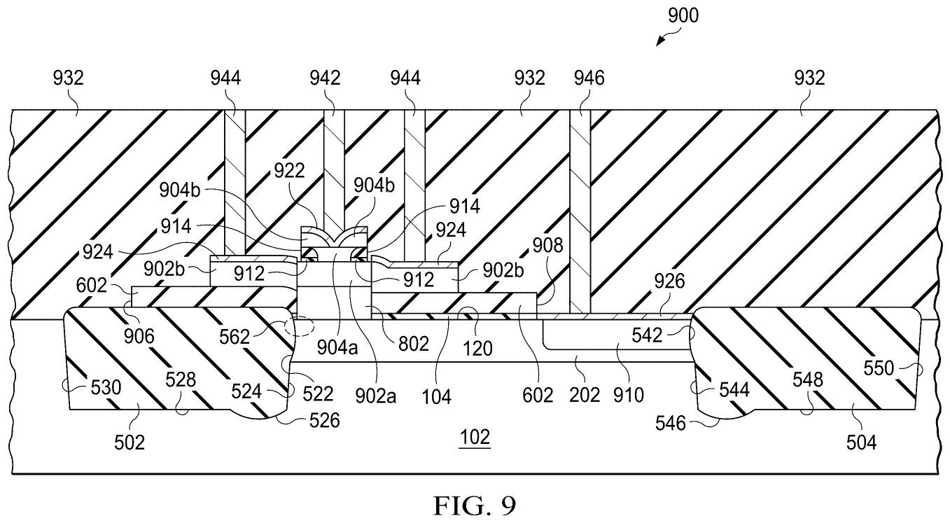

FIGS. 1 through 8 are respective cross-sectional views of a semiconductor device in intermediate stages of manufacturing according to some examples. The method illustrated in these figures may be implemented to form the semiconductor device 900 (e.g., a BJT) of FIG. 9.

Referring to FIG. 1, a first pedestal dielectric sub-layer 104 is formed over a semiconductor substrate 102. The semiconductor substrate 102 includes a semiconductor material that is monocrystalline. The semiconductor substrate 102 has an upper surface 120 in and/or on which devices (e.g., the BJT) are formed. The upper surface 120 may be a monocrystalline surface of the monocrystalline semiconductor material of the semiconductor substrate 102. The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. In some examples, the semiconductor material is or includes silicon (Si), silicon germanium (SiGe), gallium arsenide (GaAs), gallium nitride (GaN), the like, or a combination thereof. In the illustrated example, the semiconductor material (e.g., silicon) of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

The first pedestal dielectric sub-layer 104 is formed over and on the upper surface 120 of the semiconductor substrate 102. In some examples, the first pedestal dielectric sub-layer 104 is or includes silicon oxide, which may be formed by in situ steam generation (ISSG) oxidation. The first pedestal dielectric sub-layer 104 may also be, for example, a pad oxide layer. Another dielectric material and/or formation or deposition technique may be implemented.

Although not illustrated, an alignment mark may be formed in the semiconductor substrate 102. The alignment mark may be formed laterally within, e.g., a scribe line that will be consumed by dicing when the semiconductor substrate 102 is singulated. Forming the alignment mark may include depositing a photoresist (e.g., by spin-on) over the first pedestal dielectric sub-layer 104 and patterning the photoresist to have an opening using photolithography. Then, the alignment mark is formed through the first pedestal dielectric sub-layer 104 and in the semiconductor substrate 102 through the opening of the photoresist. Using the patterned photoresist as a mask, an etch process, such as an anisotropic etch like a reactive ion etch (RIE), is performed to etch the first pedestal dielectric sub-layer 104 and the semiconductor substrate 102 to form the alignment mark. After forming the alignment mark, the photoresist is removed. The photoresist may be removed using an ashing, for example. As indicated subsequently, the alignment mark may be used to align photolithography masks that are used for patterning photoresists that are used for implanting a dopant for an n-type doped sub-collector region and for etching trenches for isolation structures.

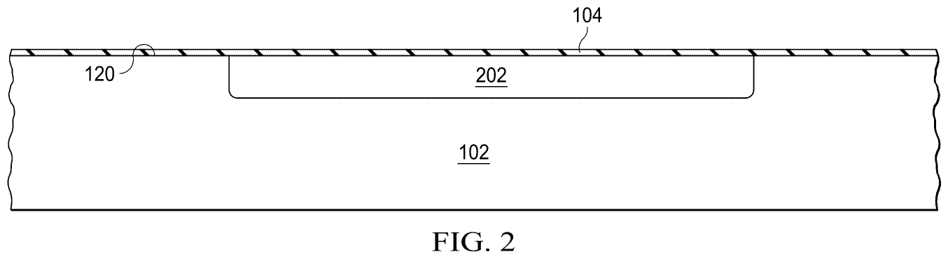

Referring to FIG. 2, an n-type doped sub-collector region 202 is formed in the semiconductor substrate 102. The n-type doped sub-collector region 202 may be formed by masking areas of the semiconductor substrate 102 where an n-type doped sub-collector region is not to be formed and implanting n-type dopants into the semiconductor substrate 102. The masking may be by a photoresist that is patterned using photolithography, which may use a photolithography mask aligned using the alignment mark. In some examples, a dose of the implantation of the n-type dopant is equal to or greater than a dose of the dopant that amorphizes the semiconductor substrate 102 where the dopant is implanted. For example, assuming the n-type dopant includes phosphorus, the dose of implanting phosphorous may be equal to or greater than 5×10¹⁴ cm⁻² (e.g., equal to or greater than 1×10¹⁵ cm⁻²) to amorphize silicon. Further, carbon may also be implanted, such as to reduce diffusion of phosphorus in silicon, and the dose of implanting carbon may be equal to or greater than 3×10¹⁵ cm⁻² to amorphize silicon. In some examples, arsenic may be implanted instead of or in addition to implanting phosphorus. Assuming the n-type dopant includes arsenic, the dose of implanting arsenic may be equal to or greater than 1×10¹⁴ cm⁻² to amorphize silicon. Following the implantation, the mask (e.g., photoresist) is removed, such as by an ashing and/or a wet process.

Following the implantation, forming the n-type doped sub-collector region 202 further includes performing an anneal process on the semiconductor substrate 102. The anneal process activates the dopants implanted for the n-type doped sub-collector region 202 and recrystallizes the semiconductor material of the semiconductor substrate 102 that was amorphized by the implantation of the dopant of the n-type doped sub-collector region 202. In some examples, the anneal process is a rapid thermal anneal (RTA). The RTA may reach a peak temperature of equal to or greater than 500° C., such as in a range from 500° C. to 1,200° C. (e.g., 1,000° C.), and may have a duration of equal to or less than 2 minutes. For example, an RTA may reach a peak temperature of 1,050° C. with a ramping of temperature at a rate of 35° C. per second over a duration of 30 seconds. The RTA may be performed in an ambient environment that includes oxygen (O₂) gas, a forming gas, the like, or a combination thereof. In other examples, other anneal processes may be implemented, such as a furnace anneal.

Following the anneal process, the n-type doped sub-collector region 202 is crystallized generally to the crystalline orientation of the semiconductor substrate 102. Crystalline defects, such as stacking faults and/or twin defects, above a detectable threshold are not generated (e.g., no stacking faults and/or twin defects are generated) in the n-type doped sub-collector region 202 when the n-type doped sub-collector region 202 is recrystallized. For example, using a transmission electron microscope (TEM) to detect crystalline defects (e.g., stacking faults and/or twin defects), no perceptible phase contrast may be present in the TEM image in the semiconductor material of the semiconductor substrate 102 in the n-type doped sub-collector region 202 relative to a bulk region of the semiconductor material of the semiconductor substrate 102. The absence of an amorphous surface, such as an amorphous dielectric material (e.g., an oxide), extending into the semiconductor material of the semiconductor substrate 102 may permit reducing or avoiding generating crystalline defects (e.g., stacking faults and/or twin defects) above a detectable threshold when the n-type doped sub-collector region 202 is recrystallized.

The n-type doped sub-collector region 202 extends from the upper surface 120 of the semiconductor substrate 102 into a depth in the semiconductor substrate 102. A concentration of the n-type doped sub-collector region 202 is greater than a concentration of the p-type dopant of the semiconductor substrate 102. The concentration of the n-type doped sub-collector region 202 may be a high concentration, such as equal to or greater than 1×10¹⁸ cm⁻³ (e.g., equal to or greater than 3×10²⁰ cm⁻³). In some examples, the n-type doped sub-collector region 202 is doped with an n-type dopant with a concentration in a range from 1×10¹⁸ cm⁻³ to 5×10²⁰ cm⁻³. Another dopant and/or other doping concentrations may be implemented.

Although the semiconductor substrate 102 and n-type doped sub-collector region 202 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

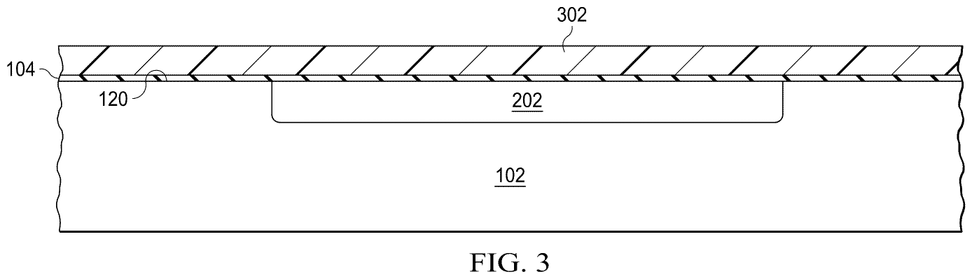

Referring to FIG. 3, a hardmask layer 302 is formed over the first pedestal dielectric sub-layer 104. The hardmask layer 302 may include or be silicon nitride, polysilicon, or another appropriate material. The hardmask layer 302 may be formed by a deposition process, such as chemical vapor deposition (CVD), plasma enhanced CVD (PECVD), furnace diffusion process, or the like.

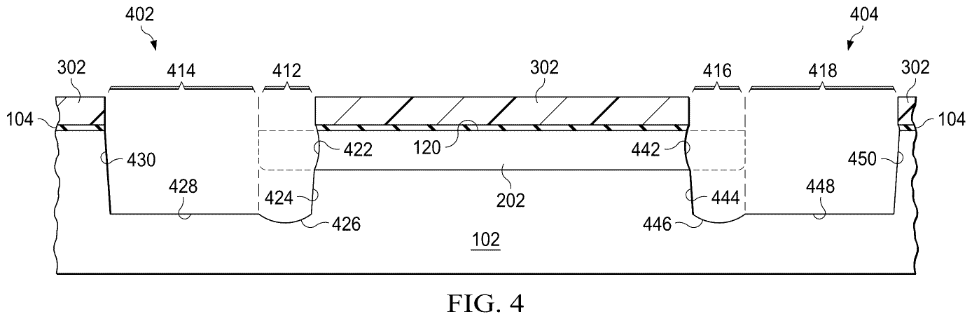

Referring to FIG. 4, trenches 402, 404 are formed in the semiconductor substrate 102. The trenches 402, 404 are formed through the hardmask layer 302 and the first pedestal dielectric sub-layer 104 and in the semiconductor substrate 102. The trenches 402, 404 are formed to a depth in the semiconductor substrate 102 below a depth to which the n-type doped sub-collector region 202 is formed. Although illustrated as trenches 402, 404 in the cross-section of FIG. 4, the trenches 402, 404 may be a continuous trench laterally surrounding, encircling, or encompassing, and hence, laterally defining, an area of the semiconductor substrate 102. The area includes the n-type doped sub-collector region 202.

The trenches 402, 404 may be formed by patterning the hardmask layer 302 and etching the first pedestal dielectric sub-layer 104 and semiconductor substrate 102 using the patterned hardmask layer 302 as a mask. Patterning the hardmask layer 302 may include depositing a photoresist (e.g., by spin-on) over the hardmask layer 302 and patterning the photoresist to have openings corresponding to the trenches 402, 404 using photolithography, which may use a photolithography mask aligned using the alignment mark. Then, the hardmask layer 302 is etched through the openings of the photoresist. Using the patterned photoresist as a mask, an etch process, such as an anisotropic etch like an RIE, is performed to etch the hardmask layer 302 to pattern the hardmask layer 302.

Following patterning the hardmask layer 302, another etch process (e.g., RIE) is performed using the patterned hardmask layer 302 as a mask to form the trenches 402, 404 in the semiconductor substrate. The etch process (e.g., RIE) may include using chlorine (Cl₂) gas, hydrogen bromide (HBr) gas, or a combination thereof. The trenches 402, 404 are etched through the first pedestal dielectric sub-layer 104 and into the semiconductor substrate 102.

The trench 402, 404 are etched in the semiconductor substrate 102 where portions of the trenches 402, 404 laterally overlap where the n-type doped sub-collector region 202 was formed. The trench 402 laterally overlaps where the n-type doped sub-collector region 202 was formed at a laterally overlapping portion 412 and does not laterally overlap where the n-type doped sub-collector region 202 was formed at a laterally non-overlapping portion 414 laterally distal from the n-type doped sub-collector region 202 relative to the laterally overlapping portion 412. Similarly, the trench 404 laterally overlaps where the n-type doped sub-collector region 202 was formed at a laterally overlapping portion 416 and does not laterally overlap where the n-type doped sub-collector region 202 was formed at a laterally non-overlapping portion 418 laterally distal from the n-type doped sub-collector region 202 relative to the laterally overlapping portion 416.

Etching the trenches 402, 404 may include implementing etch rates of the semiconductor material of the semiconductor substrate 102 doped with the dopant of the n-type doped sub-collector region 202 that differ from etch rates of the semiconductor material of the semiconductor substrate 102 that is not doped with such dopant. As illustrated, a lateral etch rate of the semiconductor material of the semiconductor substrate 102 doped with the dopant of the n-type doped sub-collector region 202 is greater than a lateral etch rate of the semiconductor material of the semiconductor substrate 102 that is not doped with such dopant. Hence, the sidewall of the trench 402 adjoining the n-type doped sub-collector region 202 has a non-planar sidewall portion 422 and a planar sidewall portion 424 underlying the non-planar sidewall portion 422. The planar sidewall portion 424 is below the n-type doped sub-collector region 202. The non-planar sidewall portion 422 is formed by etching where the semiconductor material of the semiconductor substrate 102 was doped with the dopant of the n-type doped sub-collector region 202. The planar sidewall portion 424 is formed by etching where the semiconductor material of the semiconductor substrate 102 is not doped with the dopant of the n-type doped sub-collector region 202. Generally, the non-planar sidewall portion 422 may be curved, such as concave from the perspective of the trench 402, and may bulge or extend laterally outward into the semiconductor substrate 102 relative to the planar sidewall portion 424. The non-planar sidewall portion 422 extends laterally into the semiconductor substrate 102 from the planar sidewall portion 424.

Further, as illustrated, a vertical etch rate of the semiconductor material of the semiconductor substrate 102 doped with the dopant of the n-type doped sub-collector region 202 is greater than a vertical etch rate of the semiconductor material of the semiconductor substrate 102 that is not doped with such dopant. Hence, the bottom surface of the trench 402 laterally aligned with the laterally overlapping portion 412 has a non-planar bottom surface portion 426 and a planar bottom surface portion 428 laterally aligned with the laterally non-overlapping portion 414. The non-planar bottom surface portion 426 is formed by etching, at least in part, where the semiconductor material of the semiconductor substrate 102 was doped with the dopant of the n-type doped sub-collector region 202. The planar bottom surface portion 428 is formed by etching where the semiconductor material of the semiconductor substrate 102 is not doped with the dopant of the n-type doped sub-collector region 202. Generally, the non-planar bottom surface portion 426 may be curved, such as concave from the perspective of the trench 402, and may bulge or extend vertically lower into the semiconductor substrate 102 relative to the planar bottom surface portion 428. The non-planar bottom surface portion 426 extends vertically lower (e.g., to a greater depth) into the semiconductor substrate 102 from the planar bottom surface portion 428. The trench 402 has a planar sidewall 430 opposite from the sidewall that includes the non-planar sidewall portion 422.

More generally, the planar sidewall portion 424, planar bottom surface portion 428, and planar sidewall 430 are or conform to a reentrant profile. The non-planar sidewall portion 422 bulges or extends laterally from the reentrant profile of the planar sidewall portion 424, and the non-planar bottom surface portion 426 bulges or extends vertically below the reentrant profile of the planar bottom surface portion 428.

Similar to the trench 402, the trench 404 has a sidewall that includes a non-planar sidewall portion 442 and a planar sidewall portion 444 underlying the non-planar sidewall portion 442. The trench 404 also has a bottom surface that includes a non-planar bottom surface portion 446 and a planar bottom surface portion 448.

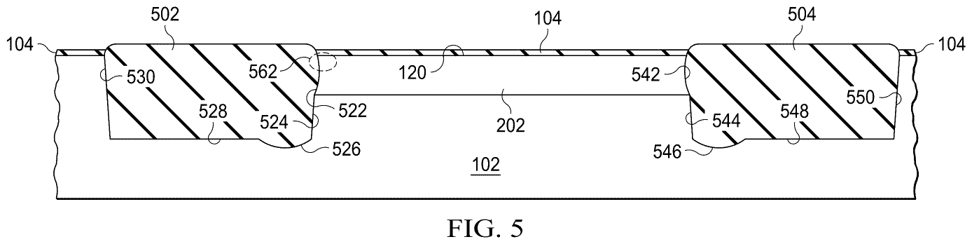

Referring to FIG. 5, the trenches 402, 404 are filled with isolation material to form isolation structures 502, 504. In the illustrated example, the isolation structures 502, 504 are shallow trench isolation structures (STIs) extending from the upper surface 120 of the semiconductor substrate 102 into the semiconductor substrate 102. As illustrated, the isolation structures 502, 504 are also through the first pedestal dielectric sub-layer 104 and are raised above the upper surface 120 of the semiconductor substrate 102. The isolation structures 502, 504 may include, for example, a liner layer, such as including silicon oxide or silicon nitride, conformally along surfaces of a respective trench 402, 404 through the first pedestal dielectric sub-layer 104 and in the semiconductor substrate 102 and a fill isolation material, such as silicon oxide, over and on the liner layer. The liner layer may be conformally deposited in the trenches 402, 404 and over the hardmask layer 302, such as by PECVD, or formed on exposed surfaces of the trenches 402, 404, such as by an oxidation process like ISSG. The fill isolation material may be deposited over the liner layer, such as by high aspect ratio CVD (HAR-CVD), flowable CVD (FCVD), or the like. Excess fill isolation material and liner layer may be removed from over the hardmask layer 302 by a planarization process, such as a chemical mechanical polish (CMP). The fill isolation material and liner layer may be etched back to a target depth from a top surface of the hardmask layer 302, such as by a wet or dry etch selective to the material of the fill isolation material and liner layer, which may be a wet etch process. The hardmask layer 302 may then be removed by an etch selective to the hardmask layer 302, which may be a wet etch process.

Like described above with respect to the trenches 402, 404, the isolation structures 502, 504 may be a continuous isolation structure laterally surrounding, encircling, or encompassing, and hence, laterally defining an area (e.g., an active area) of the upper surface 120 of the semiconductor substrate 102 in and/or on which the BJT is to be formed. As indicated subsequently, an active portion (e.g., a base layer) of the BJT may extend laterally beyond the area of the upper surface 120 of the semiconductor substrate 102 in and/or on which the BJT is formed and may be over, e.g., the isolation structure 502. Due to the filling of the trenches 402, 404 to form the isolation structures 502, 504, the isolation structures 502, 504 have surfaces that conform to the surfaces of the trenches 402, 404. The isolation structure 502 has a non-planar sidewall portion 522, a planar sidewall portion 524, a non-planar bottom surface portion 526, a planar bottom surface portion 528, and a planar sidewall 530 that correspond to the non-planar sidewall portion 422, planar sidewall portion 424, non-planar bottom surface portion 426, planar bottom surface portion 428, and planar sidewall 430, respectively. Hence, the isolation structure 502 includes the planar sidewall portion 524, planar bottom surface portion 528, and planar sidewall 530 that are or conform to a reentrant profile. The isolation further includes the non-planar sidewall portion 522 that bulges or extends laterally from the reentrant profile of the planar sidewall portion 524 and includes the non-planar bottom surface portion 526 that bulges or extends vertically below the reentrant profile of the planar bottom surface portion 528. Similarly, the isolation structure 504 has a non-planar sidewall portion 542, a planar sidewall portion 544, a non-planar bottom surface portion 546, a planar bottom surface portion 548, and a planar sidewall 550 that correspond to the non-planar sidewall portion 442, planar sidewall portion 444, non-planar bottom surface portion 446, planar bottom surface portion 448, and planar sidewall 450, respectively. The isolation structures 502, 504 are each laterally asymmetric (e.g., asymmetric around an axis normal to the upper surface 120 of the semiconductor substrate 102).

As described above, crystalline defects, such as stacking faults and/or twin defects, above a detectable threshold are not present (e.g., no stacking faults and/or twin defects are present) originating from an interface between the respective isolation structure 502, 504 and the semiconductor substrate 102 in the n-type doped sub-collector region 202. For example, stacking faults and/or twin defects above a detectable threshold are not in a corner region 562 in the semiconductor substrate 102 at the isolation structure 502 and the upper surface 120 of the semiconductor substrate 102.

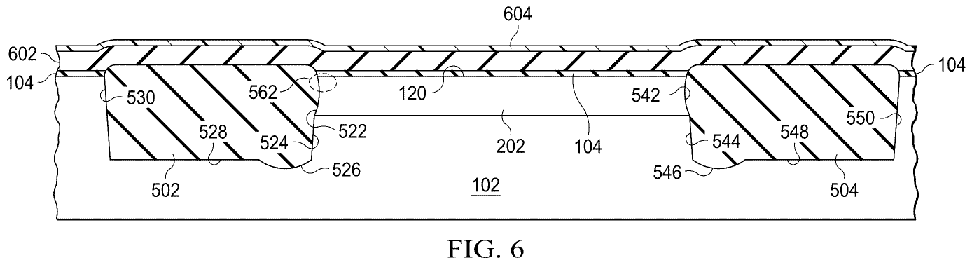

Referring to FIG. 6, a second pedestal dielectric sub-layer 602 is formed over and on the first pedestal dielectric sub-layer 104, and a hardmask layer 604 is formed over and on the second pedestal dielectric sub-layer 602. The second pedestal dielectric sub-layer 602 may also be formed over and on the isolation structures 502, 504. In some examples, the second pedestal dielectric sub-layer 602 is or includes silicon oxide (e.g., a tetraethyl orthosilicate (TEOS) oxide), which may be deposited by CVD, such as PECVD. Another dielectric material and/or formation or deposition technique may be implemented. In some examples, the hardmask layer 604 is or includes silicon nitride, which may be deposited by CVD. Any dielectric material that may be selectively etched relative to the second pedestal dielectric sub-layer 602 and/or the first pedestal dielectric sub-layer 104 may be implemented for the hardmask layer 604, and any appropriate deposition process may be implemented to form the hardmask layer 604.

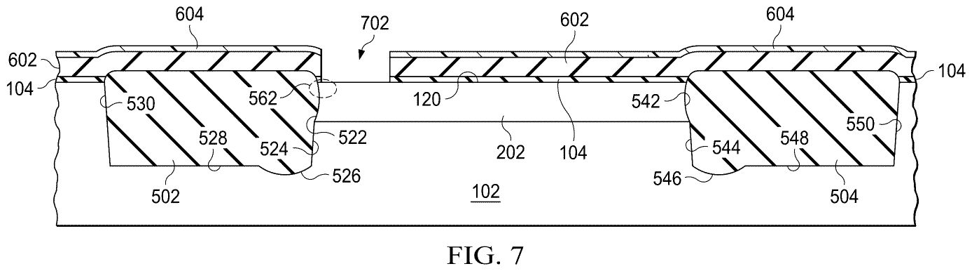

Referring to FIG. 7, the hardmask layer 604, the second pedestal dielectric sub-layer 602, and the first pedestal dielectric sub-layer 104 are etched to form a collector opening 702 through the hardmask layer 604, the second pedestal dielectric sub-layer 602, and the first pedestal dielectric sub-layer 104. The upper surface 120 of the semiconductor substrate 102 is exposed through the collector opening 702. The collector opening 702 generally extends from proximate to (or some lateral distance from) the isolation structure 502 laterally away from the isolation structure 502 in the area laterally surrounded by the isolation structures 502, 504. The hardmask layer 604, the second pedestal dielectric sub-layer 602, and the first pedestal dielectric sub-layer 104 may be etched using appropriate photolithography and etching processes. For example, an anisotropic etch, such as an RIE, may be implemented.

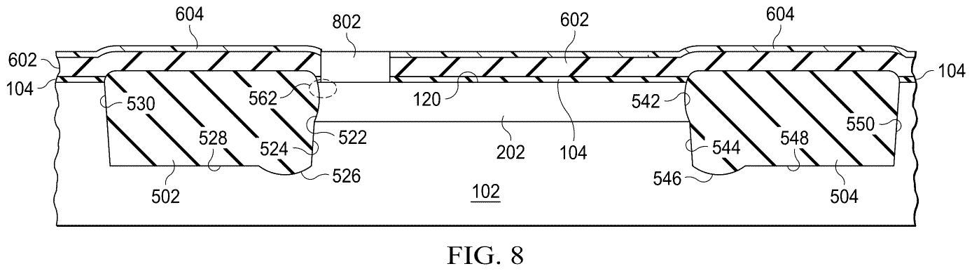

Referring to FIG. 8, a collector layer 802 is formed over (e.g., on) the upper surface 120 of the semiconductor substrate 102 and in the collector opening 702. In some examples, the collector layer 802 is or includes a semiconductor layer doped with an n-type dopant (e.g., a same dopant type as the n-type doped sub-collector region 202). In some examples, the collector layer 802 is or includes silicon. In some examples, the collector layer 802 is doped with an n-type dopant with a concentration in a range from 1×10¹⁹ cm⁻³ to 1×10²¹ cm⁻³. The collector layer 802 may be epitaxially grown on the upper surface 120 of the semiconductor substrate 102. The collector layer 802 may be epitaxially grown by a selective epitaxial growth process in some examples. The epitaxial growth of the collector layer 802 on the upper surface 120 of the semiconductor substrate 102 may result in the collector layer 802 being monocrystalline. Further, the collector layer 802 may be in situ doped during the epitaxial growth process (e.g., the selective epitaxial growth process). The epitaxial growth process may be a CVD process, such as a low pressure CVD (LPCVD), reduced pressure CVD (RPCVD), metal organic CVD (MOCVD), or the like. Other materials, dopant type, dopant concentration, and/or deposition process may be implemented.

Subsequent to the formation of the collector layer 802, processing may proceed as described in U.S. patent application Ser. No. 18/520,527, filed on Nov. 27, 2023, entitled “SEMICONDUCTOR PROCESSING INTEGRATION FOR BIPOLAR JUNCTION TRANSISTOR (BJT)”, which is incorporated herein by reference in its entirety. Such processing may continue through formation of the BJT. Such processing includes forming a base layer over (e.g., on) the collector layer 802 and forming an emitter layer over (e.g., on) the base layer.

FIG. 9 is a cross-sectional view of a semiconductor device 900 according to some examples. The semiconductor device 900 is or includes a BJT. The BJT includes the collector layer 802, a base layer 902 (e.g., monocrystalline base layer 902a and polycrystalline base layer 902b), and an emitter layer 904 (e.g., monocrystalline emitter layer 904a and polycrystalline emitter layer 904b). As illustrated, the BJT does not include a raised base layer, and in other examples, the BJT may include a raised base layer on the base layer, as described in U.S. patent application Ser. No. 18/520,527.

In some examples, the base layer 902 is or includes a semiconductor layer doped with a p-type dopant (e.g., an opposite dopant type as the collector layer 802). In some examples, the base layer 902 is or includes silicon germanium. In some examples, the base layer 902 is doped with a p-type dopant with a concentration in a range from 1×10¹⁷ cm⁻³ to 1×10²¹ cm⁻³. The base layer 902 may also be doped with carbon (C) to prevent or reduce diffusion of the p-type dopant. In some examples, the emitter layer 904 is or includes a semiconductor layer doped with an n-type dopant (e.g., an opposite dopant type from the base layer 902). In some examples, the emitter layer 904 is or includes silicon. In some examples, the emitter layer 904 is doped with an n-type dopant with a concentration in a range from 1×10¹⁹ cm⁻³ to 1×10²¹ cm⁻³. Other doping concentrations of the base layer 902 and/or emitter layer 904 may be implemented. As described, with the collector layer 802 and the emitter layer 904 being doped with n-type dopants, and the base layer 902 being doped with a p-type dopant, the BJT in the described example is an NPN BJT. In other examples, the BJT may be a PNP BJT.

The collector layer 802 is over and on the upper surface 120 of the semiconductor substrate 102 and is through an opening in a pedestal dielectric stack (e.g., the second pedestal dielectric sub-layer 602 and first pedestal dielectric sub-layer 104), which is also over the upper surface 120 (e.g., in the area laterally surrounded by the isolation structures 502, 504) of the semiconductor substrate 102. The collector layer 802 is on the n-type doped sub-collector region 202 in the semiconductor substrate 102. The base layer 902 (e.g., the monocrystalline base layer 902a) is over and on the collector layer 802, and the base layer 902 (e.g., the polycrystalline base layer 902b) is over and on an upper surface of the pedestal dielectric stack (e.g., the second pedestal dielectric sub-layer 602).

The pedestal dielectric stack (e.g., the pedestal dielectric sub-layers 104, 602) underlies the base layer 902. The pedestal dielectric stack extends laterally from the base layer 902 (e.g., the polycrystalline base layer 902b). For example, the pedestal dielectric stack (e.g., the pedestal dielectric sub-layers 104, 602) extends over and on the isolation structure 502 laterally away from a corresponding sidewall of the polycrystalline base layer 902b to a sidewall 906 of the pedestal dielectric stack over the isolation structure 502. Additionally, the pedestal dielectric stack extends over and on the upper surface 120 of the semiconductor substrate 102 over the n-type doped sub-collector region 202 and laterally away from a corresponding sidewall of the polycrystalline base layer 902b to a sidewall 908 of the pedestal dielectric stack proximate an n-type collector contact region 910.

The n-type collector contact region 910 is in the n-type doped sub-collector region 202 in the semiconductor substrate 102. The n-type collector contact region 910 is laterally between the pedestal dielectric stack and the isolation structure 504. A concentration of the n-type dopant of the n-type collector contact region 910 is greater than the concentration of the n-type dopant of the n-type doped sub-collector region 202. In some examples, the n-type collector contact region 910 is doped with an n-type dopant with a concentration in a range from 1×10²⁰ cm⁻³ to 1×10²¹ cm⁻³. Other doping concentrations may be implemented.

The emitter layer 904 (e.g., the monocrystalline emitter layer 904a) is over and on the base layer 902 (e.g., the monocrystalline base layer 902a) and is through an opening defined by a spacer structure, and the emitter layer 904 (e.g., the polycrystalline emitter layer 904b) is over and on the spacer structure. The spacer structure includes a first dielectric spacer layer 912 and a second dielectric spacer layer 914. In some examples, the second dielectric spacer layer 914 is a dielectric material different from the dielectric material of the first dielectric spacer layer 912. In some examples, the first dielectric spacer layer 912 is silicon oxide (e.g., a TEOS oxide), and the second dielectric spacer layer 914 is silicon nitride. Other dielectric materials may be used in other examples. Other spacer structures may be implemented.

Metal-semiconductor compound 922 is on the emitter layer 904 (e.g., the polycrystalline emitter layer 904b and/or monocrystalline emitter layer 904a). Metal-semiconductor compound 924 is on the base layer 902 (e.g., the polycrystalline base layer 902b). Metal-semiconductor compound 926 is on the upper surface 120 of the semiconductor substrate 102 on the n-type collector contact region 910. The metal-semiconductor compound 922, 924, 926 may be a silicide (e.g., NiSix, TiSix, CoSix, PtSix), a germanicide, or the like.

A dielectric layer 932 is formed over the semiconductor substrate 102 (e.g., over the BJT), and metal contacts 942, 944, 946 are formed through the dielectric layer 932. The dielectric layer 932 may include one or more dielectric sub-layers. For example, the dielectric layer 932 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 932 may be or include a pre-metal dielectric (PMD), an inter-layer dielectric (ILD), or the like. The metal contacts 942, 944, 946 extend through the dielectric layer 932 and contact respective metal-semiconductor compound 922, 924, 926. The metal contacts 942, 944, 946 may each include one or more barrier and/or adhesion layers (e.g., titanium nitride (TiN), tantalum nitride (TaN), the like, or a combination thereof) conformally in a respective opening through the dielectric layer 932, and a fill metal (e.g., tungsten (W), copper (Cu), aluminum (Al), the like, or a combination thereof) over and/or on the barrier and/or adhesion layer(s).

In some examples, the BJT may be a heterojunction BJT. As indicated previously, in some examples, the collector layer 802 and the emitter layer 904 may be silicon, and the base layer 902 may include silicon germanium. Hence, in some examples, the base layer 902 may include a semiconductor material dissimilar from respective semiconductor materials of the collector layer 802 and emitter layer 904. The dissimilar semiconductor materials may form one or more heterojunctions in the BJT, and the BJT may therefore be a heterojunction BJT.

As stated previously, the reduction of crystalline defects (e.g., stacking faults and/or twin defects) at, e.g., the corner region 562 may reduce leakage of the BJT in FIG. 9. Reducing crystalline defects at the corner region 562 may permit the collector layer 802 to be formed in close proximity to the isolation structure 502, which may reduce a base-to-collector capacitance. Reduced leakage and reduced base-to-collector capacitance may result in improved electrical performance of the BJT.

Although various examples have been described in detail, it should be understood that various changes, substitutions, and alterations can be made therein without departing from the scope defined by the appended claims.

What is claimed is:

1. A method, comprising:
forming a sub-collector region in a semiconductor substrate;
after forming the sub-collector region, forming an isolation structure in the semiconductor substrate, the isolation structure having a sidewall adjoining the sub-collector region; and
forming a collector layer over the sub-collector region.

2. The method of claim 1, wherein forming the sub-collector region includes:
implanting a dopant of the sub-collector region into the semiconductor substrate; and
performing an anneal after implanting the dopant.

3. The method of claim 2, wherein implanting the dopant in the semiconductor substrate amorphizes the semiconductor substrate where the dopant is implanted.

4. The method of claim 2, wherein a dose of the dopant during implanting the dopant is equal to or exceeds 5×10¹⁴ cm⁻².

5. The method of claim 1, wherein the sidewall has a non-planar profile adjoining the sub-collector region.

6. The method of claim 1, wherein forming the isolation structure includes etching a trench in the semiconductor substrate utilizing an etch process, and wherein the etch process removes:
a first portion of the semiconductor substrate including the sub-collector region at a first etch rate; and
a second portion of the semiconductor substrate that does not include the sub-collector region at a second etch rate less than the first etch rate.

7. The method of claim 1, wherein a bottom surface of the isolation structure has a non-planar portion on a lateral side proximate to the sub-collector region and has a planar portion on a lateral side distal from the sub-collector region.

8. A method, comprising:
implanting a dopant into a semiconductor substrate;
performing an anneal process after implanting the dopant, a sub-collector region including the dopant being formed in the semiconductor substrate as a result of performing the anneal process;
etching a trench in the semiconductor substrate after performing the anneal process, the trench having a sidewall adjoining the sub-collector region;
filling the trench with an isolation material forming an isolation structure; and
forming a collector layer over the sub-collector region.

9. The method of claim 8, wherein implanting the dopant into the semiconductor substrate amorphizes a portion of the semiconductor substrate where the dopant is implanted.

10. The method of claim 9, wherein performing the anneal process recrystallizes the amorphized portion of the semiconductor substrate.

11. The method of claim 8, wherein a dose of the dopant during implanting the dopant is equal to or exceeds 5×10¹⁴ cm⁻².

12. The method of claim 8, wherein the sidewall has a non-planar portion adjoining the sub-collector region.

13. The method of claim 12, wherein the sidewall has a planar portion below the non-planar portion, the planar portion being lower in the semiconductor substrate than the sub-collector region.

14. The method of claim 8, wherein etching the trench includes utilizing an etch process that removes a first portion of the semiconductor substrate including the sub-collector region at a first etch rate and removes a second portion of the semiconductor substrate that does not include the sub-collector region at a second etch rate less than the first etch rate, the first portion vertically adjoining the second portion.

15. The method of claim 8, wherein a bottom surface of the isolation structure has a non-planar portion on a lateral side proximate to the sub-collector region.

16. The method of claim 15, wherein the bottom surface of the isolation structure has a planar portion on a lateral side distal from the sub-collector region.

17. A semiconductor device, comprising:
a semiconductor substrate;
an isolation structure in the semiconductor substrate, the isolation structure including a first sidewall with a non-planar profile, the isolation structure laterally surrounding at least in part an area of a bipolar junction transistor (BJT) in the semiconductor substrate;
a sub-collector region of the BJT in the area, the sub-collector region laterally adjoining the first sidewall of the isolation structure;
a collector layer of the BJT on the area;
a base layer of the BJT on the collector layer; and
an emitter layer of the BJT on the base layer.

18. The semiconductor device of claim 17, wherein the sub-collector region has a concentration of an n-type dopant equal to or greater than 1×10¹⁸ cm⁻³.

19. The semiconductor device of claim 17, wherein the first sidewall of the isolation structure includes a planar portion and a non-planar portion, the planar portion conforming to a reentrant profile, the non-planar portion extending laterally from the reentrant profile.

20. The semiconductor device of claim 17, wherein the isolation structure is laterally asymmetric, wherein a second sidewall of the isolation structure opposite from the first sidewall of the isolation structure has a reentrant profile.
